(19) United States
(12) Patent Application Publication
(10) Pub. No.: US 2022/0328452 A1
(43) Pub. Date: Oct. 13, 2022

(54) SEMICONDUCTOR DEVICE FOR INTEGRATING POWER GATE CIRCUIT USING SILICON CONNECTION LAYER

(71) Applicant: WUXI ESIONTECH CO., LTD., Wuxi, Jiangsu (CN)

(72) Inventors: Jicong FAN, Wuxi (CN); Yueer SHAN, Wuxi (CN); Yanfeng XU, Wuxi (CN); Yanfei ZHANG, Wuxi (CN); Hua YAN, Wuxi (CN)

(21) Appl. No.: 17/311,943

(22) PCT Filed: Dec. 30, 2020
(86) PCT No.: PCT/CN2020/141240

§ 371 Date: Jun. 8, 2021

(30) Foreign Application Priority Data
Jul. 1, 2020 (CN) 202010620154.6

(51) Int. Cl. H01L 25/065; H01L 23/00; H03K 19/17736; H01L 23/538

(52) U.S. Cl. CPC H01L 25/0652; H01L 24/16; H03K 19/17744; H01L 23/5381; H01L 2924/1431; H01L 2924/14335; H01L 2924/1427; H01L 2224/16148; H01L 2224/16227; H01L 2224/16238

(57) ABSTRACT

A semiconductor device includes an active silicon connection layer therewithin to integrate a die. A power terminal of a die functional module within the die is connected to a connection point lead-out terminal through a silicon stack connection point. A power gating circuit is arranged within the silicon connection layer. A power output terminal of the power gating circuit within the silicon connection layer is connected to the corresponding connection point lead-out terminal of the die and thus connected to the power terminal of the die function module, so that the power gate circuit can control power supply to the die function module according to an obtained sleep control signal, and the idle die function module can enter into a sleep state to save power.

### CROSS-REFERENCE TO RELATED APPLICATIONS

This application is a national stage of International Application No. PCT/CN2020/141240, filed on Dec. 30, 2020, which claims priority to Chinese Patent Application No. 202010620154.6, filed on Jul. 1, 2020. Both of the aforementioned applications are hereby incorporated by reference in their entireties.

### TECHNICAL FIELD

The present disclosure relates to the field of semiconductor technology, in particular to a semiconductor device that integrates a power gate circuit using a silicon connection layer.

### BACKGROUND

Semiconductor chips are widely used in various fields, especially in emerging fields such as mobile communications, data centers, navigation guidance and autonomous driving. With the rapid development of integrated circuit manufacturing processes and the increase in the operating frequency of semiconductor devices, the functions of semiconductor devices are rapidly increasing, while the increase in power consumption will lead to an increase in heat generation and a decrease in reliability of the chips, which has become an urgent problem.

### SUMMARY

In response to the above problems and technical needs, the inventors have proposed a semiconductor device that uses a silicon connection layer to integrate a power gate circuit.

A semiconductor device for integrating a power gate circuit using a silicon connection layer is provided. The semiconductor device includes a substrate, a silicon connection layer stacked on the substrate, and a die stacked on the silicon connection layer. The die includes a die function module and a silicon stack connection module therewithin. The silicon stack connection module includes a plurality of silicon stack connection points therewithin, and the die is further provided with connection point lead-out terminals. A power terminal of the die function module is connected to corresponding silicon stack connection point, and the silicon stack connection points are connected to corresponding connection point lead-out terminals through a top metal wire within a re-distribution layer. Input and output ports of the die are connected to the substrate through silicon vias on the silicon connection layer. The silicon connection layer includes a power gate circuit, and the power gate circuit includes a power input terminal, a power output terminal and a sleep control terminal. The connection point lead-out terminal of the die connected to the power terminal of the die function module within the die is connected to the power output terminal of the power gate circuit through a metal wire within the silicon connection layer. The power input terminal of the power gate circuit is connected to a power supply. The sleep control terminal obtains a sleep control signal corresponding to the die function module within the die. The power gate circuit controls power supply of the die function module according to the sleep control signal so that the die function module enters into a sleep mode when it is idle.

Further, the semiconductor device includes a plurality of the die function modules therewithin, the power terminal of each die function module is connected to the corresponding connection point lead-out terminal, and the connection point lead-out terminal connected to the power terminal of the die function module is connected to the power output terminal of the power gate circuit through a metal wire within the silicon connection layer.

Further, a plurality of the power gate circuits are arranged within the silicon connection layer. The power input terminals of all the power gate circuit are connected together and connected to the power supply. The sleep control terminals of all the power gate circuit are connected together and obtain the sleep control signal, the power output terminals of all the power gate circuit are connected together and connected to the power terminal of the die function module. The power gate circuits are connected in parallel to control power supply of the die function module.

Further, the semiconductor device includes a plurality of the die function modules therewithin, the power terminal of each die function module is connected to the corresponding connection point lead-out terminal. A plurality of the power gate circuits are arranged within the silicon connection layer. Each power gate circuit corresponds to one or more of the die function modules and the power output terminal of the power gate circuit is connected to the power terminal of the corresponding die function module. The power gate circuit obtains the sleep control signal of the corresponding die function module and controls power supply of the die function module.

Further, the semiconductor device includes one die that includes a plurality of the die function modules therewithin, so that the plurality of die function modules within the semiconductor device are within the same die. Alternatively, the semiconductor device includes a plurality of dies stacked on the silicon connection layer, and the silicon connection layer covers all the dies. Each die includes the die function module therewithin, so that the plurality of die function modules within the semiconductor device include a plurality of die function modules within the same die and/or a plurality of die function modules within the plurality of dies.

Further, the die within the semiconductor device includes at least one FPGA die.

Further, a silicon connection layer function module is further arranged within the silicon connection layer. A power terminal of the silicon connection layer function module is connected to the power output terminal of the corresponding power gate circuit through a metal wire within the silicon connection layer. The power gate circuit controls power supply of the silicon connection layer function module.

Further, the sleep control terminal of the power gate circuit is connected to an external port of the semiconductor device to obtain externally inputted sleep control signal. Alternatively, the silicon connection layer includes a monitoring circuit connected to the die, the sleep control terminal of the power gate circuit is connected to the monitoring circuit within the silicon connection layer through a metal wire within the silicon connection layer, the monitoring circuit within the silicon connection layer inputs the sleep control signal to the power gate circuit. Alternatively, the sleep control terminal of the power gate circuit is connected to another circuit module within the die in which the corresponding die function module is located, the another circuit module of the die other than the die function module inputs the sleep control signal to the power gate circuit. Alternatively, the semiconductor device includes a plurality of dies all stacked on the silicon connection layer. The sleep control terminal of the power gate circuit is connected to another die, and the another die inputs the sleep control signal to the power gate circuit.

Further, the sleep control signal is provided by a programmable module within a FPGA die, the programmable module providing the sleep control signal includes at least one of a CLB, a BRAM and a DSP

Further, the programmable module providing the sleep control signal is dynamically configured by a dynamic programmable port of the FPGA die within which the programmable module is located.

Further, a voltage regulator capacitor is provided at a power input terminal of the power gate circuit, with a capacitance greater than a predetermined capacitance.

Further, the power gate circuit is arranged within the silicon connection layer close to the die function module within the die corresponding to the power gate circuit.

Further, the power gate circuit is implemented by transistors larger than a predetermined size.

### BRIEF DESCRIPTION OF THE DRAWINGS

FIG. 1 is a cross-sectional view of a structure of a semiconductor device of the present disclosure.

FIG. 2 is a schematic diagram of the circuit structure of a power gate circuit within a silicon connection layer.

FIG. 3 is a schematic diagram of a circuit in which a power gate circuit is connected to control a plurality of die function modules within one die.

FIG. 4 is a schematic diagram of a circuit in which multiple power gate circuits are connected in parallel to control one die function module within one die.

FIG. 5 is a schematic diagram of a circuit in which a plurality of power gate circuits are connected to control a plurality of die function modules within a die.

FIG. 6 is a cross-sectional view of a structure of the semiconductor device of the present disclosure including a plurality of dies therewithin.

FIG. 7 is a schematic diagram of a circuit in which a power gate circuit is connected to control a plurality of die function modules within a plurality of dies.

FIG. 8 is a schematic diagram of a circuit in which a plurality of power gate circuits are connected to control a plurality of die function modules within a plurality of dies.

### DETAILED DESCRIPTION

Specific embodiments of the present disclosure are further described below in conjunction with the accompanying drawings.

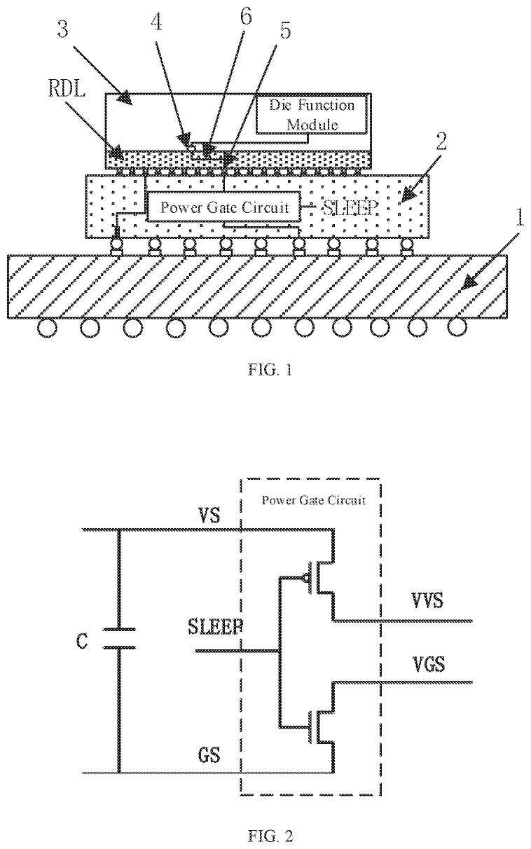

The present disclosure discloses a semiconductor device for integrating a power gate circuit by using a silicon connection layer. Referring to FIG. 1, the semiconductor device includes a substrate 1, a silicon connection layer 2 stacked on the substrate 1, and a die 3 stacked on the silicon connection layer 2. Practically, it also includes an external package housing and pins for leading out signals, etc., which are not shown in FIG. 1.

The die 3 includes a die function module and a silicon stack connection module therewithin. The silicon stack connection module includes a plurality of silicon stack connection points 4 therewithin, and connection point lead-out terminals 5 are also provided on the die 3. A power terminal of the die function module is connected to the corresponding silicon stack connection point 4, and the silicon stack connection point 4 is connected to the corresponding connection point lead-out terminal 5 through a top metal wire 6 within the re-distribution layer (RDL). The input and output ports of the die 3 are also connected to the substrate 1 through silicon vias on the silicon connection layer 2.

The silicon connection layer 2 in the present disclosure is an active silicon connection layer, and silicon connection layer 2 includes a power gate (PG) circuit therewithin. The power gate circuit in the following figures of the disclosure is denoted by PG circuit. The power gate circuit includes a power input terminal, a power output terminal, and a sleep control terminal. The specific circuit structure of the power gate control circuit is an existing circuit structure. Referring to FIG. 2, the power gate control circuit consists of transistors, including PMOS and NMOS transistors connected in series. The gates of two MOS transistors are connected to form the sleep control terminal SLEEP. Power input leads VS and GS pin, and power output leads VVS and VGS are lead out from the two transistors connected in series. Since the power gate circuit is arranged within the silicon connection layer 2 which is larger and less difficult to manufacture than the die, transistors with a large size can be used within the power gate circuit, i.e., the power gate circuit is implemented based on transistors larger than a predetermined size which is usually the maximum size of transistors that can be accommodated in the die. Further, a voltage regulator capacitor C is provided at a power input terminal of the power gate circuit. As shown in FIG. 2, the voltage regulator capacitor C is connected between the leads VS and GS of the power input terminal, and the voltage regulator capacitor C is usually a high-value capacitor, i.e., the capacitance of the voltage regulator capacitor C is larger than a predetermined capacitance. The predetermined capacitance value is configured according to actual needs. The regulator capacitor C can stabilize the power supply when the power gate circuit is switched on or switched off.

Metal wires are further provided within the silicon connection layer 2. The connection point lead-out terminal 5 of the die 3 which is connected to the power terminal of the internal die function module is connected to the power output terminal of the power gate circuit through the metal wire within the silicon connection layer 2. The power input terminal of the power gate circuit is connected to a power supply, and is typically connected to a power terminal on the substrate 1 to obtain the outside power supply. The sleep control terminal (SLEEP) of the power gate circuit obtains the sleep control signal corresponding to the connected die function module, and the power gate circuit is switched on or switched off according to the sleep control signal. When the power gate circuit is switched off, the power gate circuit cuts off power supply to the die function module, so that the die function module can enter into a sleep mode when it is idle, so as to reduce power consumption. There may be other modules within the die 3 that do not need power supply control, so they can be directly connected to the power supply.

When the semiconductor device integrates one die on a silicon connection layer 2, based on the basic circuit structure described above, the present disclosure has a variety of expanded structures that can be achieved.

1. A power gate circuit controls power supply of one die function module within a die 3, i.e., a circuit structure as described above is used.

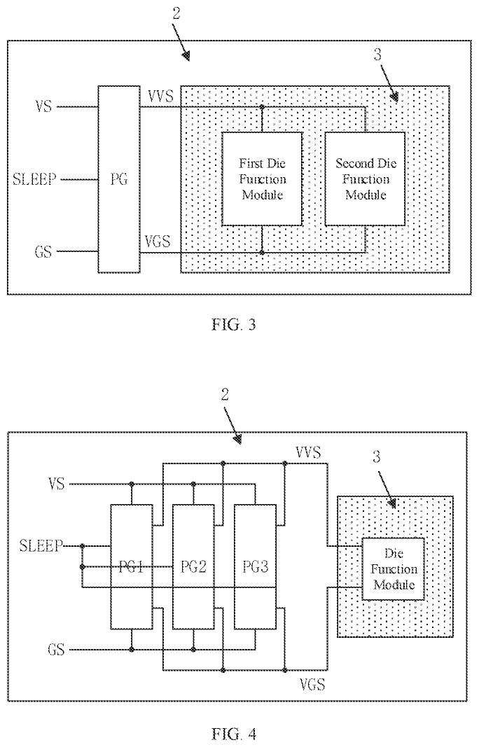

2. A power gate circuit controls power supply of multiple die function modules within a die 3, i.e., a die 3 includes a plurality of die function modules therewithin, and the power terminal of each die function module is connected to a corresponding connection point lead-out terminal 5 respectively. The connection point lead-out terminals 5 of the die 3 connected to the power terminals of the die function modules are connected to the power output terminal of the same power gate circuit through the metal wire within the silicon connection layer 2, respectively. Referring to FIG. 3, as an example, a PG circuit is used to control two die function modules within a die 3. A power gate circuit corresponds to multiple die function modules within a die 3, and the power gate circuit controls power supply of a die function module according to the corresponding sleep control signal of the die function module.

3. Multiple power gate circuits control power supply of the same die function module within a die 3, that is, a plurality of power gate circuits with the above structure are arranged within the silicon connection layer 2. The power input terminals of the power gate circuits are all connected together and connected to the power supply. The sleep control terminals of the power gate circuits are connected together and obtain sleep control signals. The power output terminals of the power gate circuits are connected together and connected to the power terminal of the die function module. That is, the multiple power gate circuits form a parallel structure. Referring to FIG. 4, which takes three PG circuits arranged within the silicon connection layer 2 as an example, these multiple power gate circuits correspond to the same die function module and control power supply of the die function module according to the sleep control signal. The parallel structure can effectively reduce the voltage drop.

4. Multiple power gate circuits control multiple die function modules within a die 3, i.e., a die 3 includes a plurality of die function modules, and the power terminals of the die function module are connected to corresponding connection point lead-out terminals respectively. At the same time, a plurality of power gate circuits with the above structure are arranged within the silicon connection layer 2. The power input terminals of the power gate circuits are all connected to the power supply. Each power gate circuit corresponds to one or more die function modules, and the power output terminal of the power gate circuit is connected to the corresponding power terminal(s) of the its corresponding die function module(s). The sleep control terminal of the power gate circuit obtains the sleep control signal of the corresponding die function module it is connected to. The connection structure is as described above in the first case when corresponding to one die function module, and the connection structure is as described above in the second case when corresponding to multiple die function modules. Each power gate circuit controls power supply of each die function module connected to it according to the sleep control signal corresponding to each die function module, and the multiple power gate circuits jointly control power supply of multiple die function modules. Referring to FIG. 5, two PG circuits within the silicon connection layer 2 control two die function modules within the die 3, and each PG circuit controls one die function module, for example.

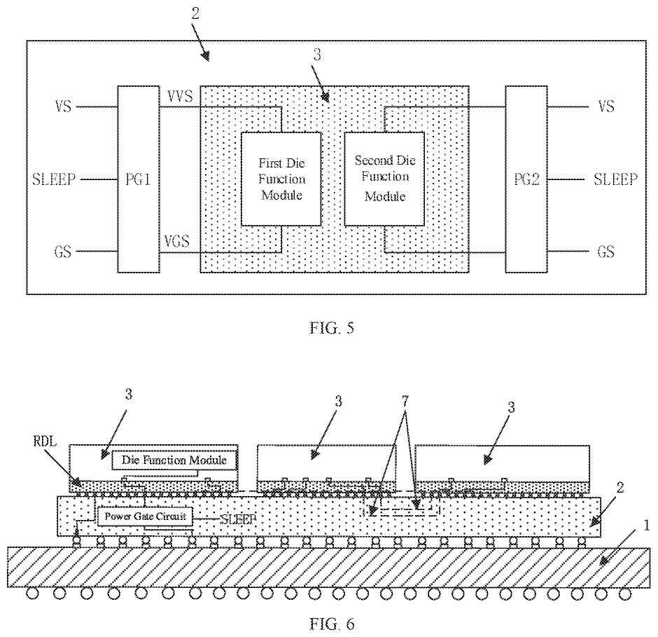

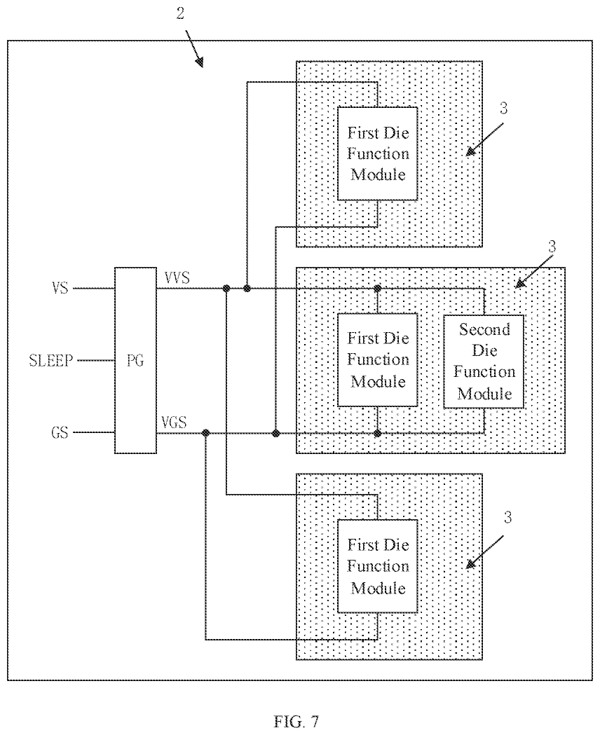

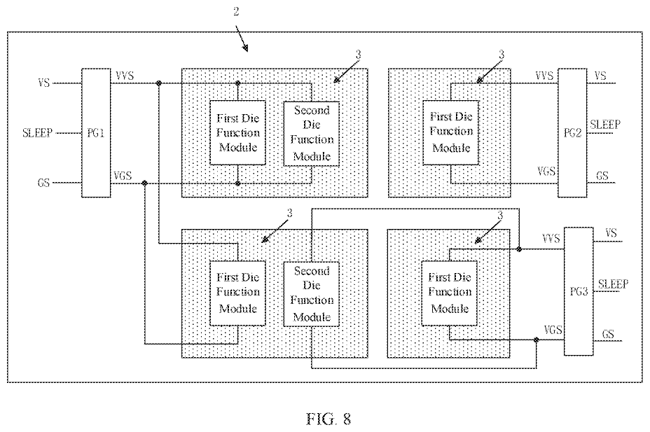

Further, the semiconductor device of the present disclosure may also be a multi-die device, also known as a Chiplet core integration device. Referring to FIG. 6, the semiconductor device includes a plurality of dies 3, which are stacked on the silicon connection layer 2 and the silicon connection layer 2 covers all the dies 3, which may be arranged on the silicon connection layer 2 in a one-dimensional direction, as shown in FIG. 7. The multiple dies 3 can also be arranged on the silicon connection layer 2 in a two-dimensional stacking manner, i.e., in the horizontal plane along the horizontal and longitudinal directions, as shown in FIG. 8. The multiple dies can be reasonably arranged on the silicon connection layer 2 and compactly arranged on the silicon connection layer 2 according to the shape and area of each die 3 to make the overall area of the device smaller and the interconnection performance among the dies better. Cross-die wires 7 are further arranged within the silicon connection layer 2, and the interconnection among the dies 3 is realized through the cross-die wires 7 according to the circuit interconnection needs. The silicon connection layer 2 includes two cross-vertical cross-die wires 7 arranged therewithin, which are arranged in layers without affecting each other, and the span and direction of the wires can be flexibly arranged, so that each die can be connected to any other die through the cross-die wires 7 within the silicon connection layer 2. It should be noted that both the cross-die wire 7 between the dies within the silicon connection layer 2 and the metal wire between the die and the power gate circuit are essentially metal wires, and different terms are used in the present disclosure to differentiate the connected circuit structures. In the present disclosure, the die within the semiconductor device includes at least one FPGA die, and the multi-die device is realized as a multi-die FPGA when all the dies 3 within the semiconductor device are FPGA dies.

When the semiconductor device integrates multiple dies on the silicon connecting layer 2, the present disclosure also has a variety of expanded structures that can be achieved.

1. A power gate circuit connects and controls power supply of a die function module(s) within one die of the multi-die device, which may be one or more die function modules within one die. This case is similar to those of the various applications described above where there is only one die, and will not be described in the present disclosure.

2. A power gate circuit connects and controls power supply of the die function modules within the multiple dies in the multi-die device, and for each die connected to the power gate circuit, the power gate circuit can further connect and control one or more die function modules within it. The specific connection between the power gate circuit and the power terminal of the die function modules within each die can refer to the above case where there is only one die. Referring to FIG. 7, a power gate circuit connects and controls die function modules within three dies 3, and connects and controls power supply of one die function module within two of the dies, and connects and controls power supply of two die function modules within the other die, for example.

3. A plurality of power gate circuits connect and control a die function module(s) within one die in the multi-die device, and may be connected to control power supply of one or more die function modules within one die. This case is similar to a corresponding single-die case described above, and will not be repeated in the present disclosure. This case is similar to a corresponding case described above where there is only one die, and will not be described in the present disclosure.

4. Multiple power gate circuits connect and control multiple die function modules within multiple dies in a multi-die device, and each power gate circuit connects and controls a die function module(s) within one or more dies. The expanded applications in which each power gate circuit connects and controls a die function module(s) within each die can refer to the first case above. In this case, each power gate circuit may control all die function modules within a die, or multiple power gate circuits may cross-control die function modules within multiple dies, when some die function modules within a die may be controlled by one power gate circuit and some other die function modules by other power gate circuits. Referring to FIG. 8, three PG circuits control die function modules within four dies, for example.

Regardless of the above-mentioned implementations of the internal circuit structure of the semiconductor device, the power gate circuit is arranged within the silicon connection layer 2 close to the die function module within the die it is connected to and controls, so that the connection path between the power gate circuit and the corresponding dies is as short as possible.

In addition, a silicon connection layer function module is arranged within the silicon connection layer 2, which can be of a variety of circuit structures, such as a signal delay regulation circuit connected between the dies and composed of active devices to adjust signal delay, a clock tree circuit that provides a clock signal to the die, or a monitoring circuit (Monitor) to monitor the operating status of the die. The power terminal of the silicon connection layer function module is connected to the power output terminal of the corresponding power gate circuit through a metal wire within the silicon connection layer. The power gate circuit can control power supply of the silicon connection layer function module using the above-mentioned control process for the die function module, so that the silicon connection layer function module can enter into a sleep mode to reduce power consumption when it is idle. Similarly, the power supply of one or more silicon connection layer function modules can be controlled by one power gate circuit, or multiple power gate circuits.

In the above circuit structures, the sleep control signal obtained by the sleep control terminal of each power gate circuit has various sources as follows.

(1) The signal is from outside of such semiconductor device. The sleep control terminal of the power gate circuit is connected to an external port of such semiconductor device so as to obtain an externally inputted sleep control signal from the external port to switch it on or off.

(2) The signal is from inside of the semiconductor device, and from a monitor circuit (Monitor) within the silicon connection layer 2. This applies to the case where a monitor circuit of the silicon connection layer 2 is connected to each die. In this case, the sleep control terminal of the power gate circuit is connected to the monitor circuit within the silicon connection layer through a metal wire within the silicon connection layer. The monitoring circuit within the silicon connection layer inputs a sleep control signal to the power gate circuit to switch on or switch off the power gate circuit.

(3) The signal is from inside of the semiconductor device, and from the die where the die function module to be controlled by the power gate circuit is located. The die includes other circuit modules in addition to the die function module to be controlled by the power gate circuit, and the sleep control terminal of the power gate circuit is connected to the corresponding connection point lead-out terminal to connect with the other circuit modules within the die. The other circuit modules input sleep control signals to the power gate circuit to switch on or switch off the power gate circuit.

(4) The signal is from inside of the semiconductor device, and from a die other than the die within which the die function module to be controlled by the power gate circuit is located. The sleep control terminal of the power gate circuit is connected to the other die, and the other die inputs a sleep control signal to the power gate circuit to switch on or switch off the power gate circuit.

When the die within the semiconductor device includes at least one FPGA die and the sleep control signal is provided by the FPGA die, the sleep control signal is provided by a programmable module within the FPGA die, and the programmable module providing the sleep control signal includes at least one of CLB, BRAM and DSP. Correspondingly, the other circuit modules in the third case above are programmable modules within the FPGA die, and in the fourth case above, the sleep control terminal of the power gate circuit is connected to the corresponding programmable module of the other die, i.e. the FPGA die. Further, the programmable module used to provide the sleep control signal can be dynamically configured by a dynamic programmable port of the FPGA die within which it is located.

According to various embodiments of the present disclosure, a semiconductor device id provided that uses a silicon connection layer to integrate a power gate circuit. The semiconductor device is provided with an active silicon connection layer therewithin. A power gate circuit is arranged within the silicon connection layer. By connecting the power gate circuit of the silicon connection layer to the power terminal of the die function module within the die, the power gate circuit can control power supply to the die function module according to an obtained sleep control signal, so that the idle die function module can enter into a sleep state to save power. Arranging the power gate circuit within the silicon connection layer has low manufacture difficulty, and can avoid the problem of high processing difficulty and large chip area otherwise caused by arranged it within the die.

The above description is only preferred embodiments of the present disclosure, and the present disclosure is not limited to the above embodiments. It is understood that other improvements and variations directly derived or associated by a person skilled in the art without departing from the spirit and conception of the present disclosure shall be considered to be included in the scope of protection of the present disclosure.

1. A semiconductor device for integrating a power gate circuit using a silicon connection layer, comprising a substrate, a silicon connection layer stacked on the substrate, and a die stacked on the silicon connection layer;
the die comprises a die function module and a silicon stack connection module therewithin; the silicon stack connection module comprises a plurality of silicon stack connection points therewithin, and the die is further provided with connection point lead-out terminals; a power terminal of the die function module is connected to corresponding silicon stack connection point, and the silicon stack connection points are connected to corresponding connection point lead-out terminals through a top metal wire within a re-distribution layer; input and output ports of the die are connected to the substrate through silicon vias on the silicon connection layer;
the silicon connection layer comprises a power gate circuit, and the power gate circuit comprises a power input terminal, a power output terminal and a sleep control terminal; the connection point lead-out terminal of the die connected to the power terminal of the die function module within the die is connected to the power output terminal of the power gate circuit through a metal wire within the silicon connection layer; the power input terminal of the power gate circuit is connected to a power supply; the sleep control terminal obtains a sleep control signal corresponding to the die function module within the die; the power gate circuit controls power supply of the die function module according to the sleep control signal so that the die function module enters into a sleep mode when it is idle.

2. The semiconductor device according to claim 1, wherein the semiconductor device comprises within a plurality of the die function modules, the power terminal of each die function module is connected to the corresponding connection point lead-out terminal, and the connection point lead-out terminal connected to the power terminal of the die function module is connected to the power output terminal of the power gate circuit through a metal wire within the silicon connection layer.

3. The semiconductor device according to claim 1, wherein a plurality of the power gate circuits are arranged within the silicon connection layer; the power input terminals of all the power gate circuit are connected together and connected to the power supply; the sleep control terminals of all the power gate circuit are connected together and obtain the sleep control signal, the power output terminals of all the power gate circuit are connected together and connected to the power terminal of the die function module; the power gate circuits are connected in parallel to control power supply of the die function module.

4. The semiconductor device according to claim 1, wherein the semiconductor device comprises within a plurality of the die function modules, the power terminal of each die function module is connected to the corresponding connection point lead-out terminal; a plurality of the power gate circuits are arranged within the silicon connection layer; each power gate circuit corresponds to one or more of the die function modules and the power output terminal of the power gate circuit is connected to the power terminal of the corresponding die function module; the power gate circuit obtains the sleep control signal of the corresponding die function module and controls power supply of the die function module.

5. The semiconductor device according to claim 2, wherein the semiconductor device comprises one die that comprises a plurality of the die function modules therewithin, so that the plurality of die function modules within the semiconductor device are within the same die;
alternatively, the semiconductor device comprises a plurality of dies stacked on the silicon connection layer, and the silicon connection layer covers all the dies; each die comprises the die function module therewithin, so that the plurality of die function modules within the semiconductor device comprise a plurality of die function modules within the same die and/or a plurality of die function modules within the plurality of dies.

6. The semiconductor device according to claim 1, wherein the die within the semiconductor device comprises at least one FPGA die.

7. The semiconductor device according to claim 1, wherein a silicon connection layer function module is further arranged within the silicon connection layer; a power terminal of the silicon connection layer function module is connected to the power output terminal of the corresponding power gate circuit through a metal wire within the silicon connection layer; the power gate circuit controls power supply of the silicon connection layer function module.

8. The semiconductor device according to claim 1, wherein the sleep control terminal of the power gate circuit is connected to an external port of the semiconductor device to obtain externally inputted sleep control signal;
alternatively, the silicon connection layer comprises a monitoring circuit connected to the die, the sleep control terminal of the power gate circuit is connected to the monitoring circuit within the silicon connection layer through a metal wire within the silicon connection layer, the monitoring circuit within the silicon connection layer inputs the sleep control signal to the power gate circuit;
alternatively, the sleep control terminal of the power gate circuit is connected to another circuit module within the die in which the corresponding die function module is located, the another circuit module inputs the sleep control signal to the power gate circuit;
alternatively, the semiconductor device comprises a plurality of dies all stacked on the silicon connection layer; the sleep control terminal of the power gate circuit is connected to another die other than the die connected to the power output terminal of the power gate circuit, and the another die inputs the sleep control signal to the power gate circuit.

9. The semiconductor device according to claim 8, wherein the sleep control signal is provided by a programmable module within a FPGA die, the programmable module providing the sleep control signal comprises at least one of a CLB, a BRAM and a DSP.

10. The semiconductor device according to claim 9, wherein the programmable module providing the sleep control signal is dynamically configured by a dynamic programmable port of the FPGA die within which the programmable module is located.

11. The semiconductor device according to claim 1, wherein a voltage regulator capacitor is provided at a power input terminal of the power gate circuit, with a capacitance greater than a predetermined capacitance.

12. The semiconductor device according to claim 1, wherein the power gate circuit is arranged within the silicon connection layer close to the die function module within the die corresponding to the power gate circuit.

13. The semiconductor device according to claim 1, wherein the power gate circuit is implemented by transistors larger than a predetermined size.

14. A semiconductor device, comprising:
a substrate;
a silicon connection layer stacked on the substrate and comprising at least one power gate circuit, the at least one power gate circuit comprising a control terminal and a power output terminal; and
a first die stacked on the silicon connection layer and comprising a first die function module, the first die function module comprising a power terminal of the first die function connected to the power output terminal of the at least one power gate circuit.

15. A semiconductor device according to claim 14, wherein the first die further comprises a silicon stack connection module, the silicon stack connection module comprising a silicon stack connection point connected to the power terminal of the first die function module, the first die further comprising a connection point lead-out terminal connected to the power output terminal of the at least one power gate circuit, the silicon stack connection point being connected to the connection point lead-out terminal such that the power terminal of the first die function module being connected to the power output terminal of the at least one circuit.

16. A semiconductor device according to claim 15, wherein the first die comprises a second die function module having a power terminal of the second die function module connected to the power output terminal of the at least one circuit.

17. A semiconductor device according to claim 15, where the at least one power gate circuit comprises at least two power gate circuits connected in parallel and connected to the power terminal of the first die function module.

18. A semiconductor device according to claim 15, wherein the first die comprises a second die function module having a power terminal of the second die function module, and the at least one power gate circuit comprises a first power gate circuit with a power output terminal of the first power gate circuit connected to the power terminal of the first die function module and a second power gate circuit with a power output terminal of the second power gate circuit connected to a power terminal of the second die function module.

19. A semiconductor device according to claim 15, further comprising a second die stacked on the silicon connection layer and comprising a second die function module with a power terminal of the second die function connected to the power output terminal of the at least one power gate circuit.

20. A semiconductor device according to claim 15, further comprising a second die stacked on the silicon connection layer and comprising a second die function module with a power terminal of the second die function, wherein the at least one power gate circuit comprises a first power gate circuit with a power output terminal of the first power gate circuit connected to the power terminal of the first die function module and a second power gate circuit with a power output terminal of the second power gate circuit connected to a power terminal of the second die function module.
